(19) United States
(12) Patent Application Publication
(10) Pub. No.: US 2026/0052694 A1
(43) Pub. Date: Feb. 19, 2026

(54) Process to Enable Discrete Charge Trap Formation

(71) Applicant: SK hynix Inc., Gyeonggi-do (KR)

(72) Inventors: Agus TJANDRA, San Jose, CA (US); Changhyun LEE, San Jose, CA (US); Sung-Taeg KANG, San Jose, CA (US)

(21) Appl. No.: 18/806,613

(22) Filed: Aug. 15, 2024

(51) Int. Cl. H10B 43/35; H10B 43/27

(52) U.S. Cl. CPC H10B 43/35; H10B 43/27

(57) ABSTRACT

A method for forming a memory storage structure and a semiconductor memory device having the memory storage structure. The method provides a stacked structure comprising oxide layers and nitride layers, etches the nitride layers to form recesses in between the oxide layers, fills silicon into the recesses between the oxide layers, selectively nitrifies an exposed surface of the silicon in the recesses to form a charge trap in each recess, forms a tunnel oxide in contact with the charge trap, and completely removes remaining nitride layers and oxidizes a remaining portion of the silicon in each recess to form therein a blocking oxide layer against the charge trap layer. The oxide layers, the blocking oxide, the charge trap, and the tunnel oxide form the memory storage structure, and the charge trap is electrically isolated by the oxide layers in the memory structure, the blocking oxide, and the tunnel oxide.

### BACKGROUND

### 1. Field

The present invention relates to semiconductor memory devices and fabrication techniques thereof.

### 2. Description of the Related Art

A semiconductor memory device may include a plurality of memory cells capable of storing data. These memory cells may be coupled in series between select transistors to form a plurality of memory strings. Gates of the memory cells and the select transistors forming the memory strings may be stacked on each other for high integration density of the semiconductor device. A three-dimensional semiconductor device may be realized by using a gate stack structure including the gates stacked on each other. With regard to the realization of such a three-dimensional semiconductor device including the gate stack structure, various techniques for improving the operational reliability of the semiconductor device are being developed.

Semiconductor technology has advanced at a rapid pace and device dimensions have shrunk with advancing technology to provide faster processing and storage per unit space. In NAND devices, the string current needs to be high enough to obtain sufficient current to differentiate ON and OFF cells. The string current is dependent on the carrier mobility which is enhanced by enlarging the grain size of the silicon channel.

In a NAND flash, memory cells may be connected in series and an address line may be installed as a block unit. The NAND flash has advantages such as relatively low manufacturing cost, fast write speed, and suitable use for a large capacity. The vertical NAND flash memory typically stack memory cells vertically and use charge trapping structures.

Various insulators (dielectrics), semiconductors, and conductor materials are applied to process NAND devices. As an insulator material, a silicon oxide, a silicon nitride, a silicon oxynitride, a high dielectric (high-k) material, etc. may be used, and as a semiconductor material, a single crystal silicon, a polycrystalline silicon, an amorphous silicon, a germanium, a silicon-germanium, and various other compound semiconductors may be used.

As cell density increases, there is the need to process even smaller dimensional structures from the insulating and semiconductor materials being used to construct the semiconductor memory devices. In this context, embodiments of the present invention arise.

### SUMMARY

In accordance with one embodiment of the invention, there is provided a method for forming a memory storage structure. The method provides a stacked structure comprising oxide layers and nitride layers alternately stacked together, etches the nitride layers to form recesses in between the oxide layers, fills silicon into the recesses between the oxide layers, selectively nitrifies an exposed surface of the silicon in the recesses to form a charge trap in each recess, forms a tunnel oxide in contact with the charge trap, and after selectively nitrifying completely removes remaining nitride layers and oxidizes a remaining portion of the silicon in each recess to form therein a blocking oxide layer against the charge trap layer. The oxide layers, the blocking oxide, the charge trap, and the tunnel oxide form the memory storage structure, and the charge trap is electrically isolated by the oxide layers in the memory structure, the blocking oxide, and the tunnel oxide. The oxide layers, the blocking oxide, the charge trap, and the tunnel oxide form the memory storage structure, and the charge trap is electrically isolated by the oxide layers, the blocking oxide, and the tunnel oxide.

In accordance with another embodiment of the invention, there is provided a semiconductor memory device comprising: a channel layer; a tunnel oxide in contact with the channel layer; a charge trap disposed a) in a recess between oxide layers in a stacked structure and b) in contact with the tunnel oxide, wherein the charge trap comprises a silicon nitride nitrified from silicon formed in the recess between oxide layers; a blocking oxide disposed in the recess and in contact with the charge trap, wherein the blocking oxide, the charge trap, and the tunnel oxide comprises a memory storage structure for the semiconductor memory device, and the charge trap is electrically isolated by the oxide layers in the stacked structure, the blocking oxide, and the tunnel oxide.

### BRIEF DESCRIPTION OF THE DRAWINGS

FIG. 1 is a diagram illustrating stacked layer processing in accordance with embodiments of the present invention.

FIG. 2 is a diagram illustrating formation of polycrystalline silicon in recesses in a stacked layer in accordance with embodiments of the present invention.

FIG. 3 is a diagram illustrating formation of charge trap formation in a stacked layer in accordance with embodiments of the present invention.

FIG. 4 is a diagram illustrating formation of one or more channel layers in a stacked layer in accordance with embodiments of the present invention.

FIG. 5 is a diagram illustrating formation of a blocking oxide in a stacked layer in accordance with embodiments of the present invention.

FIG. 6 is a diagram illustrating overall a memory storage structure fabrication process in accordance with embodiments of the present invention.

FIG. 7 is a diagram illustrating the formation of a blocking oxide in accordance with embodiments of the present invention.

FIG. 8 is another diagram illustrating another overall a memory storage structure fabrication process in accordance with embodiments of the present invention.

FIG. 9 is a flowchart illustrating one method for forming a memory storage structure in accordance with embodiments of the present invention.

FIG. 10 is a schematic illustrating a multi-dimensional memory device in accordance with embodiments of the present invention.

FIG. 11 is a schematic illustrating a stacked memory structure in accordance with embodiments of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will convey the scope of the present invention to those skilled in the art. Throughout the disclosure, like reference numerals refer to like parts throughout the various figures and embodiments of the present invention.

A detailed description of one or more embodiments of the invention is provided below along with accompanying figures that illustrate the principles of the invention. The invention is described in connection with such embodiments, but the invention is not limited to any embodiment. The scope of the invention encompasses numerous alternatives, modifications and equivalents. Numerous specific details are set forth in the following description in order to provide a thorough understanding of the invention. These details are provided for the purpose of example, and the invention may be practiced according to the claims without some or all of these specific details. For the purpose of clarity, technical material that is known in the technical fields related to the invention has not been described in detail so that the invention is not unnecessarily obscured.

To continue advanced NAND technology scaling, there is a need to have breakthrough(s) in terms of cell scaling methodology as well as process innovation. In order to increase cell density, there are several different ways being pursued in terms of vertical and lateral scaling. As the cell spacing becomes closer, process innovation is often a driver for continuing to drive reliable cell performance, but the resultant higher cell density needs to be achieved at a reasonable cost of ownership.

In one embodiment of the present invention, overall cell reliability performances (e.g., like retention and charge trapping as well as other device metrics like program saturation) are met. In additional embodiments, the present invention provides configurations and methods for forming multi-site cells (MSC) for advanced NAND technology scaling which can support future artificial intelligence (AI) and high-end data center market segments.

One embodiment of the present invention utilizes the following innovative process to form a charge trap layer using selective nitridation where the silicon nitride layer is only formed on a silicon containing material (e.g., like amorphous silicon or poly silicon within a recess of an oxide/nitride/oxide stack), and is not formed on silicon oxide of the stack. While the present invention is not limited to any particular theory, this capability for selective nitridation is related to the N* radical species generated through a plasma process such as for example described in U.S. Pat. Appl. Publ. No. 20100297826 (the entire contents of which are incorporated herein by reference). Here, in the present invention, the generated N* radical species have sufficient energy to break silicon-silicon bonding in a silicon-containing material that the generated N* radical species react with, but do not have enough energy to break silicon dioxide bonding.

In one embodiment, the present invention performs selective nitridation under the following conditions: Temperature range 700-850 ° C. a) with one of the following process gasses pure N₂, N₂/H₂ mixture, N₂/H₂/Ar mixture, NH₃/Ar mixture, or NH₃ b) with ICP (Inductive Couple Plasma) or CCP (Capacitive Coupling Plasma) plasma sources, and c) with a processing pressure ranging from hundreds kPA or less than few tens mTorr or few Torr range depending on the plasma source configuration.

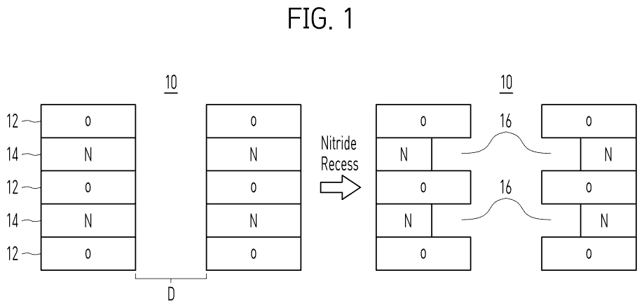

FIG. 1 is a diagram depicting a starting structure used for formation of a charge trap layer. On the left side of FIG. 1 is a stacked alternating oxide/nitride (ON) structure 10 having a central hole of diameter D. The stacked alternating ON structure 10 contains alternating layers of silicon oxide 12 and silicon nitride 14. The alternating layers of silicon oxide 12 and silicon nitride 14 can be formed from a sequence of plasma assisted chemical vapor depositions where the plasma contains during one period of time oxygen and a silicon carrier such as silane and/or disilane, and thereafter contains during another period of time nitrogen and/or ammonia and a silicon carrier such as silane and/or disilane.

As shown on the right side of FIG. 1, nitride recesses 16 are formed in the stacked alternating ON structure 10. The nitride recesses 16 may be formed by masking the outer sides of the stacked alternating ON structure 10 and exposing the interior (formed by the hole with diameter D) to wet or dry chemical etch which selectively removes part of the silicon nitride 14.

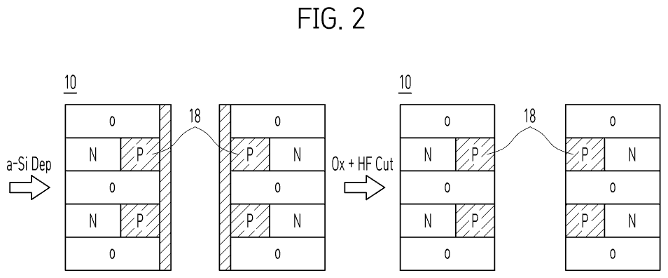

FIG. 2 is a diagram depicting on the left side the formation of polycrystalline (poly) silicon in the nitride recesses 16 and onto the inner sidewalls of the stacked alternating ON structure 10. Amorphous silicon (a-Si) can be deposited onto the inner sidewalls of the stacked alternating ON structure 10 and into recesses 16, using for example a plasma chemical vapor deposition process with silane gas as the source of silicon. The amorphous silicon can be annealed to form poly Si 18. Alternatively, poly Si 18 can be directly deposited using the plasma chemical vapor deposition process. Referring back to FIG. 2, the right side shows removal of extraneous silicon on the inner walls of the stacked alternating ON structure 10, for example by an oxidation (Ox)+hydrofluoric (HF) etching step. A mask can be formed on the top and the outside of the stacked alternating ON structure 10 to prevent amorphous silicon from forming on those surfaces. The mask would be removed after deposition of the amorphous silicon and before annealing to form poly Si 18.

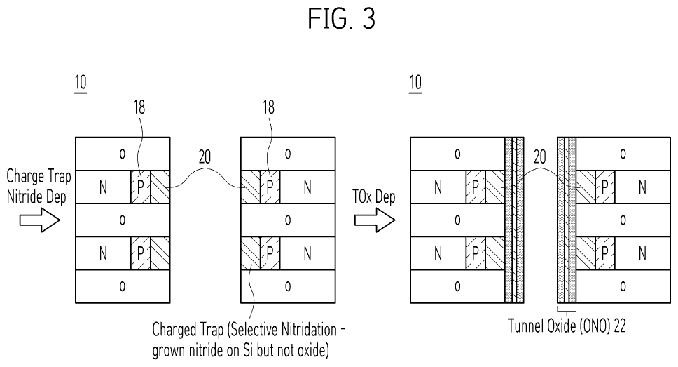

FIG. 3 is a diagram depicting charge trap formation with a selective nitridation process followed by tunnel oxide formation. As shown in FIG. 3, on the left side, a selective nitridation technique using N* radical species reacts with the exposed surfaces of poly Si 18 to form silicon nitride 20. Silicon nitride 20 (as denoted on FIG. 3) acts as a charge trap for the memory device once completed. In one embodiment, the N* radical species do not react with the layers of silicon oxide 12. The right side of FIG. 3 shows the formation of a tunnel oxide 22 (a tunneling ONO layer) on the surface of silicon nitride 20. Here, tunnel oxide 22 can be formed using a plasma chemical vapor deposition process where sequentially a) silane and oxygen and then b) silane and nitrogen and then c) silane and oxygen are reacted in the plasma. The resultant tunneling ONO layer 22 deposits non-selectively along the inner surfaces of the pair of alternating ON structure 10.

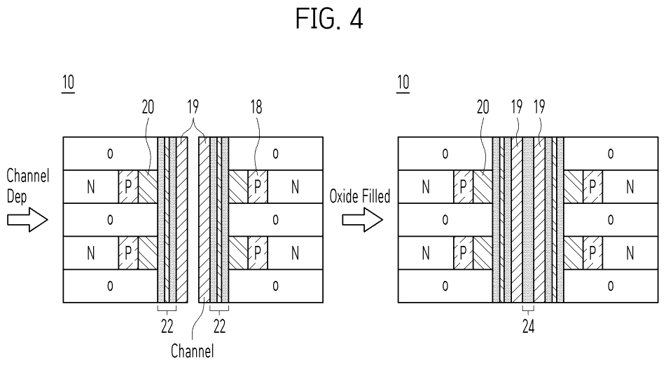

FIG. 4 is a diagram depicting channel formation by nitride removal, and then the filling of the space where the nitride was removed from with a blocking oxide. The left side of FIG. 4 shows that, after the tunnel oxide 22 is formed, a subsequent poly Si 19 formation partially fills the interior space between the pair of tunneling ONO layers 22. Subsequently, as shown on the right side of FIG. 4, a fill oxide 24 is deposited to fill the interior space of the stacked alternating ON structure 10.

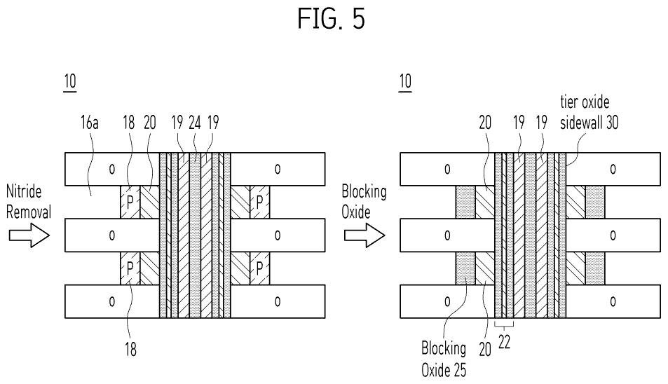

FIG. 5 is a diagram depicting nitride removal and the formation of a blocking oxide 25. The left side of FIG. 5 shows removal of silicon nitride 14 from between adjacent oxide layers in the stacked alternating ON structure 10 to form recesses 16a which expose poly Si 18. The right side of FIG. 5 shows (by oxidation of the poly Si 18) the formation of a blocking oxide 25 against silicon nitride 20 (the charge trap). As shown in FIG. 5, on the right side, each charge trap 20 is surrounded by oxides of the stacked alternating ON structure 10, the blocking oxide 25, and the tunnel oxide 22.

In one embodiment, the use of selective nitridation process permits the formation of a discrete charge trap layer (silicon nitride 20). As shown in FIG. 5, no silicon nitride remains on the tier oxide sidewall 30 of the pair of stacked alternating ON structures 10, thereby improving device reliability performance (charge retention characteristics, time to charge the trap, etc.). In addition, given that selective nitridation utilizes a silicon containing substrate/layer, prior to the selective nitridation process, an amorphous/poly silicon deposition may be used. As shown in FIG. 5, one or more of channel layers 19 are in electrical communication with the charge traps 20 via the tunnel oxide 22.

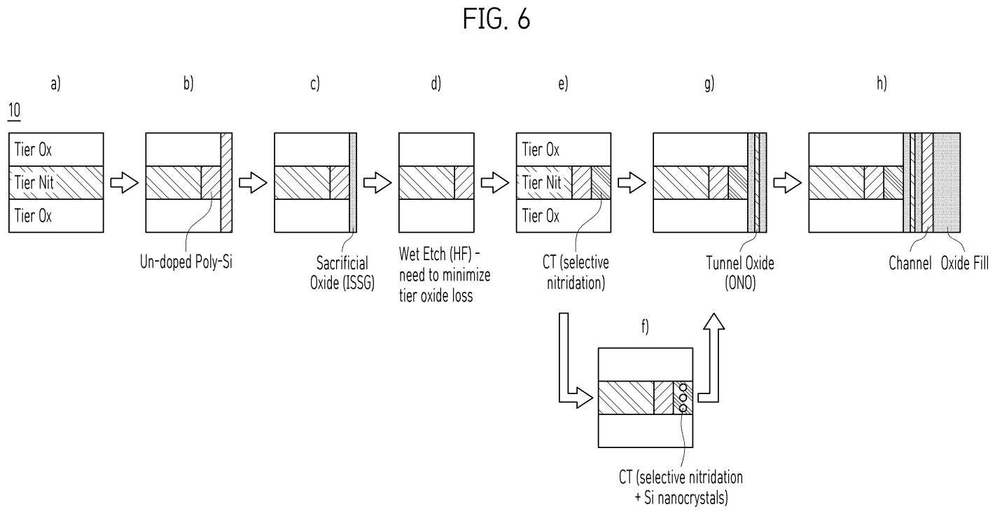

FIG. 6 is a depiction of an overall charge trap formation process showing variations from the processes depicted in FIGS. 1-5. At process a) in FIG. 6, a tier or stacked alternating ON structure 10 is provided. At process b), poly Si fills a recess between the oxide layers of the stacked alternating ON structure 10 and is formed on a vertical wall of the stacked alternating ON structure 10. At process c), unlike the processes shown in FIG. 2, the poly Si deposited on the vertical wall of the stacked alternating ON structure 10 is oxidized to form a sacrificial oxide. At process d), the sacrificial oxide is removed by a wet (or dry) etch. At process e), a selective nitridation forms silicon nitride (the charge trap (CT) layer) on the poly Si exposed after the sacrificial oxide is removed. Optionally, at process f), the selective nitrification occurs to a Si layer containing silicon nanocrystals or to a Si layer containing metal doping (such as for example Ti). At process g), a tunnel oxide ONO is formed on the silicon nitride (charge trap layer). At process h), a channel layer and a fill oxide are formed.

Accordingly, in one embodiment of the present invention, the charge trap density (the amount of charge that the charge trap can store) can be increased through: (1) using a silicon nitride stack having single or bi-layers which are Si-rich or N rich, or (2) providing silicon nanocrystals in the poly Si 18 before selective nitrification to form silicon nitride 20, or (3) providing metal doping (e.g., titanium (Ti), hafnium (Hf), etc,) in the poly Si 18 before selective nitrification to form silicon nitride 20. For utilization of Si nanocrystals, separate layers forming the Si nanocrystals would be deposited through a chemical vapor deposition technique, whereas for metal doping, metal doping can be done in-situ during for example a nitride deposition or can be done ex-situ with another process tool.

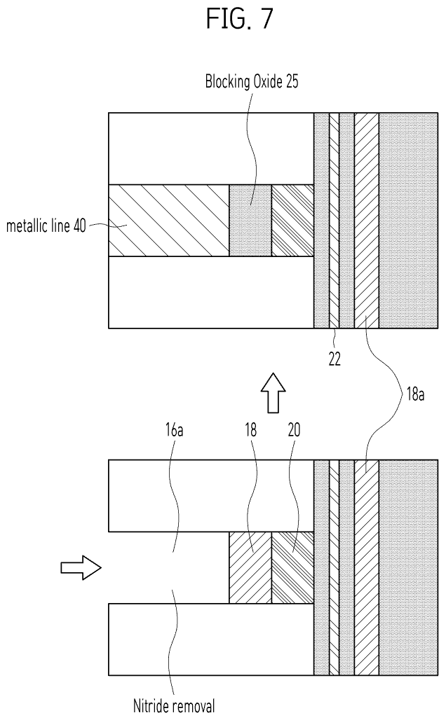

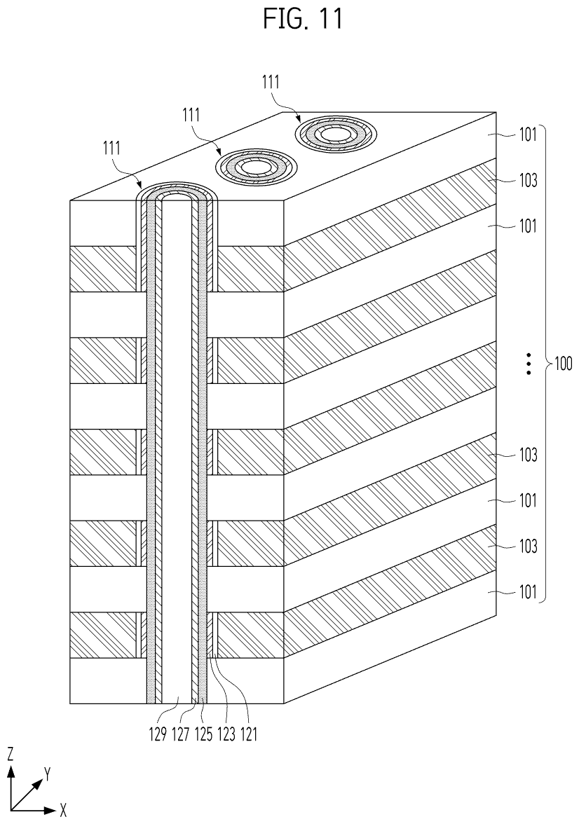

In one embodiment of the present invention, due to the presence of poly silicon between oxides of the stacked alternating ON structure 10, the blocking oxide formation can be done through silicon oxidation instead of oxidation of silicon nitride. FIG. 7 is a depiction of this process (which follows after process h) in FIG. 6) where blocking oxide 25 is grown through a poly silicon oxidation. In the lower half of FIG. 7, the nitride layer from the stack is removed, and poly Si 18 (see FIG. 5) is formed in the recess against silicon nitride (charge trap layer) 20. Afterwards, the poly Si 18 is oxidized to form blocking oxide 25. The present invention has discovered that the blocking oxide quality is improved due to no nitride remaining on the interface (as would occur if a silicon nitride layer were oxidized). Also, nitride oxidation would be expected to show more broadening on the O1s peak based on high resolution XPS spectra as compared to c-Si oxidation. The blocking oxide shows improved bonding order as measured by xray photoelectron spectroscopy (XPS) full width half maximum (FWHM) of the oxygen O1s metric from high resolution spectra data. Furthermore, as shown in FIG. 7 in the upper half, a metallic line 40 is formed in the recess 16a in contact with the blocking oxide 25. The metallic line 40 can serve as one of the word lines 103 shown in FIG. 11 in contact with blocking insulating layer 121.

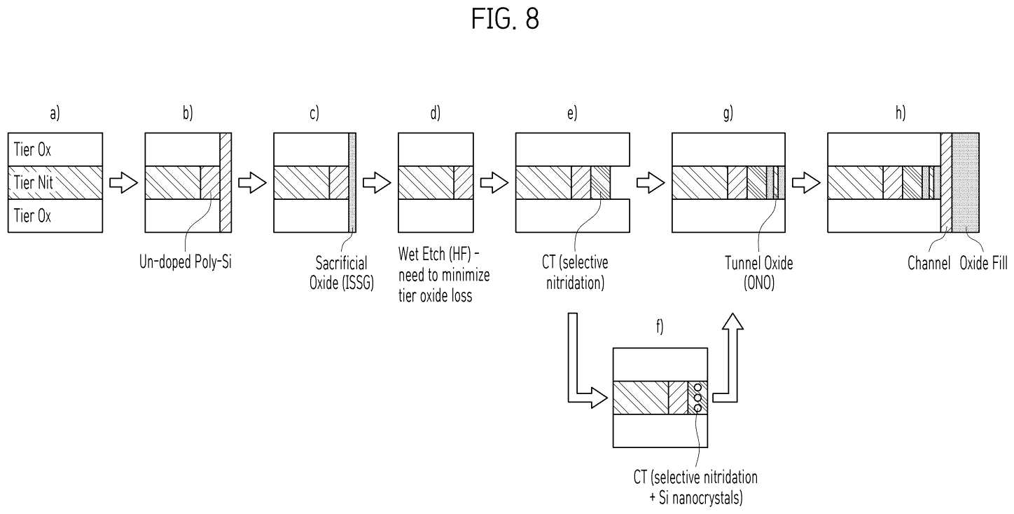

In addition, the present invention permits two different types of tunnel oxide formation. In one embodiment, the tunnel oxide (as shown in FIG. 6) can be formed outside the recess area, or the tunnel oxide (as shown in FIG. 8) can be formed inside the recess area. This flexibility assists in optimizing cell stack structures for better device performance.

FIG. 8 is a diagram depicting an overall cell formation with the tunnel oxide inside the recess. At process a) in FIG. 8, a stacked (or tier) alternating ON structure 10 is provided. At process b), poly Si fills a recess between the oxide layers of the stacked alternating ON structure 10 and is formed on a vertical wall of the stacked alternating ON structure 10. At process c), unlike the processes shown in FIG. 2, the poly Si deposited on the vertical wall of the stacked alternating ON structure 10 is oxidized to form a sacrificial oxide. At process d), the sacrificial oxide is removed by a wet (or dry) etch. At process e), a selective nitridation forms silicon nitride (the charge trap (CT) layer) on the poly Si exposed after the sacrificial oxide is removed. Optionally, at process f), the selective nitrification occurs to a Si layer containing silicon nanocrystals or to a Si layer containing metal doping (such as for example Ti). At process g), a tunnel oxide (e.g., an ONO) is formed on the silicon nitride (charge trap layer) and (unlike FIG. 6) is formed inside the recess. At process h), a channel layer and a fill oxide are formed in the same manner as shown in FIG. 4.

### Discrete Charge Trap Formation

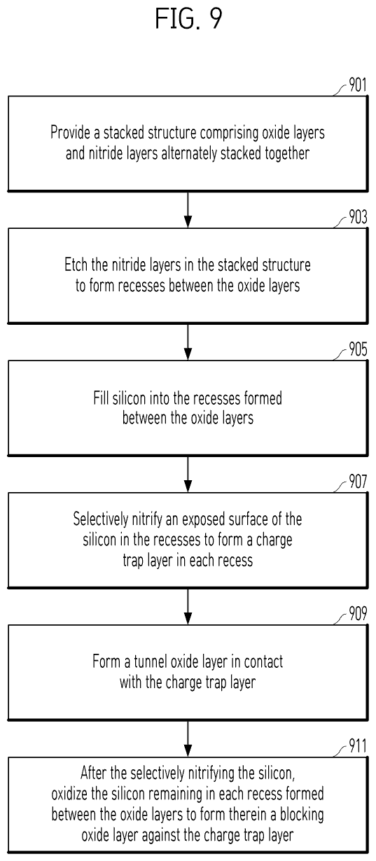

FIG. 9 is a flow chart depicting a method for forming a storage structure in accordance with one embodiment of the present invention.

At 901, the method includes providing a stacked structure comprising oxide layers and nitride layers alternately stacked together. At 903, the method includes etching the nitride layers to form recesses in between the oxide layers. At 905, the method includes filling silicon into the recesses between the oxide layers. At 907, the method includes selectively nitrifying an exposed surface of the silicon in the recesses to form a charge trap layer in each recess. At 909, the method includes forming a tunnel oxide layer in contact with the charge trap layer. At 911, the method includes, after the selectively nitrifying the silicon, completely removing remaining nitride layers and oxidizing a remaining portion of the silicon in each recess to form therein a blocking oxide layer against the charge trap layer. In one embodiment, the oxide layers, the blocking oxide layer, the charge trap layer, and the tunnel oxide layer form the memory structure. In one embodiment, the charge trap layer is electrically isolated by the oxide layers, the blocking oxide layer, and the tunnel oxide layer.

In one embodiment, the tunnel oxide layer formed comprises a tunneling oxide/nitride/oxide structure. In one embodiment, the tunnel oxide layer formed is disposed in each recess between the oxide layers. In one embodiment, the tunnel oxide layer formed is disposed along edges of the stacked structure.

In another embodiment, a channel layer (e.g., a silicon layer) is formed in contact with the tunnel oxide layer. In another embodiment, a core insulating layer is formed which fills a central hole in the stacked structure and which is in contact with the channel layer.

In another embodiment, selectively nitrifying to form the charge trap layer comprises exposing un-doped amorphous silicon in the recesses between the oxide layers to reactive nitrogen species generated from a plasma comprising at least one or more of nitrogen and ammonia. In another embodiment, selectively nitrifying to form the charge trap layer comprises exposes the un-doped amorphous silicon in the recesses between the oxide layers to reactive nitrogen species which nitrifies the un-doped amorphous silicon and does not nitrify the oxide layers. In another embodiment, selectively nitrifying to form the charge trap layer exposes the silicon (comprising silicon nanocrystals) in the recesses between the oxide layers to reactive nitrogen species. In another embodiment, selectively nitrifying exposes the silicon (comprising metal particles) in the recesses between the oxide layers to reactive nitrogen species.

In one embodiment, the filling silicon into the recesses deposits un-doped amorphous silicon into the recesses between the oxide layers. In one embodiment, the filling silicon into the recesses comprises depositing undoped amorphous silicon into the recesses between the oxide layers.

In one embodiment, the charge trap layer comprises at least two charge trap layers in the stacked structure in different recesses between the oxide layers, and the selectively nitrifying nitrifies the silicon in the different recesses to form the at least two charge trap layers.

In one embodiment, the stacked structure comprises a central hole (e.g. having a diameter D), and the different recesses are disposed across the central hole.

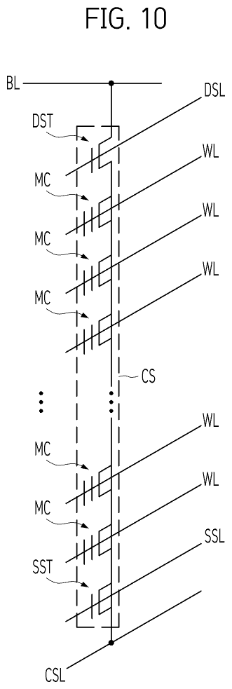

Memory System(s) Referring to FIG. 10, the semiconductor memory device of the present invention may be a three-dimensional (3D) nonvolatile memory device or a two-dimensional (2D) nonvolatile memory device. According to one embodiment, the nonvolatile memory device may be a NAND flash memory device. The NAND flash memory device may include a memory cell string CS coupled to a bit line BL and a common source line CSL.

FIG. 10 illustrates a single memory cell string CS, but a plurality of memory cell strings may be coupled in parallel between the bit line BL and the common source line CSL. The memory cell string CS may include a source select transistor SST, a plurality of memory cells MC, and a drain select transistor DST disposed between the common source line CSL and the bit line BL. Each of the memory cells MC may comprise one of the memory structures and charge traps described above with reference to FIGS. 1-8.

The source select transistor SST may control the electrical coupling between the plurality of memory cells MC and the common source line CSL. A single source select transistor SST may be disposed between the common source line CSL and the plurality of memory cells MC. Two or more source select transistors SST coupled in series to each other may be disposed between the common source line CSL and the plurality of memory cells MC. The source select transistor SST may be coupled to a source select line SSL. The operation of the source select transistor SST may be controlled by a source gate signal applied to the source select line SSL.

The plurality of memory cells MC may be disposed between the source select transistor SST and the drain select transistor DST. The memory cells MC between the source select transistor SST and the drain select transistor DST may be coupled in series to each other. The memory cells MC may be coupled to respective word lines WL. The operation of the memory cells MC may be controlled by cell gate signals applied to the word lines WL.

The drain select transistor DST may control the electrical coupling between the plurality of memory cells MC and the bit line BL. The drain select transistor DST may be coupled to a drain select line DSL. The operation of the drain select transistor DST may be controlled by a drain gate signal applied to the drain select line DSL. Each of the memory cells MC may store single-bit data or multi-bit data.

Referring to FIG. 11, the semiconductor memory device of the present invention may include a stacked body 100, a channel layer 127 (corresponding to channel layers 19 in FIG. 4), a tunnel insulating layer 125 (corresponding to tunneling ONO layer 22 in FIG. 3), a data storage layer 123 (corresponding to charge trap 20 in FIG. 3), and a blocking insulating layer 121 (corresponding to blocking oxide 25 in FIG. 7).

The stacked body 100 may include interlayer insulating layers 101 and word lines 103 (corresponding to metallic line 40 in FIG. 7) in contact with blocking insulator 121. Each of the interlayer insulating layers 101 and the word lines 103 may be parallel to an X-Y plane. The interlayer insulating layers 101 and the word lines 103 may be stacked in a Z-axis direction perpendicular to the X-Y plane. The interlayer insulating layers 101 may be disposed alternately with the word lines 103.

The word lines 103 may be insulated from each other by the interlayer insulating layers 101. The word lines 103 may be used as the gate electrodes of the memory cells MC described with reference to FIG. 1. The word lines 103 may include at least one of a doped semiconductor, metal, a metal nitride, and a metal silicide. The interlayer insulating layers 101 may include a silicon oxide layer.

The stacked body 100 may be penetrated by a hole 111 extending in the Z-axis direction. The sidewalls of the interlayer insulating layers 101 may be defined along the sidewall of the hole 111. Oxide 129 (such as oxide fill 24 in FIG. 4) can fill the space in hole 111.

Accordingly, in one embodiment of the present invention, there is provided a semiconductor memory device comprising: multiple oxides in a stacked structure; a channel layer; a tunnel oxide in contact with the channel layer; and a charge trap disposed a) in a recess between multiple oxides in the stacked structure and b) in contact with the tunnel oxide. The charge trap comprises a silicon nitride nitrified from the silicon formed in the recess between the multiple oxides. The semiconductor memory device has a blocking oxide disposed in the recess and in contact with the charge trap. The multiple oxides, the blocking oxide, the charge trap, and the tunnel oxide comprises a memory storage structure for the semiconductor memory device, and the charge trap is electrically isolated by the multiple oxides in the stacked structure, the blocking oxide, and the tunnel oxide.

In one embodiment, the tunnel oxide is disposed in between two of the multiple oxides of the stacked structure. In one embodiment, the tunnel oxide is disposed along edges of the stacked structure (e.g., along a vertical wall of the stacked structure).

In another embodiment, the charge trap comprises nanocrystals of silicon. In another embodiment, the charge trap comprises metal particles. The metal particles may comprise at least one or both of titanium and hafnium.

In one embodiment, the memory storage structure comprising the blocking oxide, the charge trap, and the tunnel oxide extends around the channel layer.

In one embodiment, the charge trap is electrically isolated by the multiple oxides in the stacked structure, the blocking oxide, and the tunnel oxide. In one embodiment, no material of the charge trap resides on edges of the stacked structure (e.g., along a vertical wall of the stacked structure).

In another embodiment, the charge trap comprises at least two charge traps in the stacked structure in different recesses between the multiple oxides.

In another embodiment, the stacked structure comprises a central hole, and the at least two charge traps comprise at least two electrically isolated charge traps disposed across the central hole.

Although the foregoing embodiments have been described in some detail for purposes of clarity of understanding, the invention is not limited to the details provided. There are many alternative ways of implementing the invention. The disclosed embodiments are illustrative and not restrictive. The present invention is intended to embrace all modifications and alternatives of the disclosed embodiment. Furthermore, the disclosed embodiments may be combined to form additional embodiments.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A method for forming a memory storage structure, comprising:
providing a stacked structure comprising oxide layers and nitride layers alternately stacked together;
etching the nitride layers to form recesses in between the oxide layers;
filling silicon into the recesses between the oxide layers;
selectively nitrifying an exposed surface of the silicon in the recesses to form a charge trap layer in each recess;
forming a tunnel oxide layer in contact with the charge trap layer;
after the selectively nitrifying the silicon, completely removing remaining nitride layers and oxidizing a remaining portion of the silicon in each recess to form therein a blocking oxide layer against the charge trap layer, and
wherein
the oxide layers, the blocking oxide layer, the charge trap layer, and the tunnel oxide layer form the memory storage structure, and
the charge trap layer is electrically isolated by the oxide layers, the blocking oxide layer, and the tunnel oxide layer.

2. The method of claim 1, wherein the tunnel oxide layer formed comprises a tunneling oxide/nitride/oxide layer.

3. The method of claim 1, wherein the tunnel oxide layer formed is disposed in each recess between the oxide layers.

4. The method of claim 1, wherein the tunnel oxide layer formed is disposed along edges of the stacked structure.

5. The method of claim 4, further comprising:
forming a channel layer in contact with the tunnel oxide layer; and
forming a core insulating layer which fills a central hole in the stacked structure and which is in contact with the channel layer.

6. The method of claim 1, wherein the selectively nitrifying to form the charge trap layer comprises exposing un-doped amorphous silicon in the recesses between the oxide layers to reactive nitrogen species generated from a plasma comprising at least one or both of nitrogen and ammonia.

7. The method of claim 6, wherein the selectively nitrifying to form the charge trap layer comprises exposing the un-doped amorphous silicon in the recesses between the oxide layers to the reactive nitrogen species which nitrifies the un-doped amorphous silicon and does not nitrify the oxide layers.

8. The method of claim 1, wherein the selectively nitrifying to form the charge trap layer comprises exposing the silicon in the recesses, in which the silicon comprises silicon nanocrystals, to reactive nitrogen species.

9. The method of claim 1, wherein the selectively nitrifying to form the charge trap layer comprises exposing the silicon in the recesses, in which the silicon comprises metal particles, to reactive nitrogen species.

10. The method of claim 1, wherein the filling silicon into the recesses comprises depositing un-doped amorphous silicon into the recesses between the oxide layers.

11. The method of claim 1, wherein the filling silicon into the recesses comprises depositing undoped amorphous silicon into the recesses between the oxide layers and annealing the undoped amorphous silicon.

12. The method of claim 1, wherein
the charge trap layer comprises at least two charge trap layers in the stacked structure in different recesses between the oxide layers, and the selectively nitrifying nitrifies the silicon in the different recesses to form the at least two charge traps layers.

13. The method of claim 12, wherein
the stacked structure comprises a central hole, and
the different recesses are recesses between the oxide layers and disposed across the central hole.

14. A semiconductor memory device comprising:
multiple oxides in a stacked structure;
a channel layer;
a tunnel oxide in contact with the channel layer;
a charge trap disposed a) in a recess between the multiple oxides in the stacked structure and b) in contact with the tunnel oxide, wherein the charge trap comprises a silicon nitride nitrified from silicon formed in the recess between the multiple oxides;
a blocking oxide disposed in the recess and in contact with the charge trap,
wherein
the multiple oxides, the blocking oxide, the charge trap, and the tunnel oxide comprise a memory storage structure for the semiconductor memory device, and
the charge trap is electrically isolated by the multiple oxides, the blocking oxide, and the tunnel oxide.

15. The device of claim 14, wherein the tunnel oxide is disposed in between two of the multiple oxides in the stacked structure.

16. The device of claim 14, wherein the tunnel oxide is disposed along edges of the stacked structure.

17. The device of claim 14, wherein the charge trap comprises nanocrystals of silicon.

18. The device of claim 14, wherein the charge trap comprises metal particles including at least one or both of titanium and hafnium.

19. The device of claim 14, the charge trap is electrically isolated by the multiple oxides in the stacked structure, the blocking oxide, and the tunnel oxide.

20. The device of claim 14, wherein no material of the charge trap material resides on edges of the stacked structure.

21. The device of claim 14, wherein
the charge trap comprises at least two charge traps in the stacked structure in different recesses between the multiple oxides.

22. The device of claim 21, wherein
the stacked structure comprises a central hole,
the at least two charge traps comprise at least two electrically isolated charge traps disposed across the central hole.
